(19) United States
(12) Patent Application Publication
(10) Pub. No.: US 2008/0042759 A1
(43) Pub. Date: Feb. 21, 2008

(54) PLL circuit

(75) Inventor: Masafumi Watanabe, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 11/892,092

(22) Filed: Aug. 20, 2007

(30) Foreign Application Priority Data
Aug. 21, 2006 (JP) 2006-224041

(51) Int. Cl. H03L 7/085; H03L 7/08; H03L 7/089

(52) U.S. Cl. 331/17

(57) ABSTRACT

A PLL circuit according to an embodiment of the present invention includes: a first charge pump circuit to control an output current in accordance with an output signal of a phase comparator; an integrating filter to remove a predetermined frequency component; a second charge pump circuit to output a larger current than the first charge pump circuit in accordance with the output signal from the phase comparator; a ripple filter to remove a ripple component; a first voltage-current converting circuit to convert an output voltage from the integrating filter into a current; a second voltage-current converting circuit to convert an output voltage from the ripple filter into a current; and a current-controlled oscillator to control a frequency of output signal based on sum total of the output current from the first voltage-current converting circuit and the output current from the second voltage-current converting circuit.

### BACKGROUND OF THE INVENTION

1. Field of the Invention

The present invention relates to a PLL circuit. In particular the invention relates to a PLL circuit including a filter that filters out noise of a voltage signal generated in accordance with a phase difference between a reference signal and an output signal.

2. Description of Related Art

In recent years, a PLL (Phase Locked Loop) circuit has been often used as an oscillating circuit incorporated in a semiconductor device. The PLL circuit controls an oscillation frequency of an output signal to match a phase of a reference signal with a phase of the output signal.

FIG. 2 is a block diagram of a general PLL circuit 100 as Related Art 1. As shown in FIG. 2, the PLL circuit 100 includes dividers 110, 111, and 117, a phase comparator 112, a charge pump circuit 113, a loop filter 114, a voltage-current converting circuit 115, and a current-controlled oscillator 116.

The phase comparator 112 compares a signal obtained by dividing a frequency of a reference signal Fin with a signal obtained by dividing a frequency of an output signal Fout of the PLL circuit 100, and then outputs a signal for controlling the charge pump circuit 113. The charge pump circuit 113 outputs a current. This current is supplied in an inflow direction or outflow direction under control in accordance with the output signal of the phase comparator 112. The loop filter 114 generates a voltage corresponding to the current output from the charge pump circuit 113. Further, the loop filter 114 filters out ripple noise and RF noise superimposed on the generated voltage. The voltage-current converting circuit 115 generates a current corresponding to the generated voltage through the loop filter 114. The current-controlled oscillator 116 outputs a signal with a frequency corresponding to the current output from the voltage-current converting circuit 115. The signal output from the current-controlled oscillator 116 is divided into an output signal Fout by the divider 117.

Further, another example of the PLL circuit is disclosed in Japanese Unexamined Patent Application Publication No. 7-79159 (Related Art 2), Japanese Unexamined Patent Application Publication No. 2001-119296 (Related Art 3), and Japanese Patent Translation Publication No. 2005-520455 (Related Art 4). FIG. 3 is a block diagram of a PLL circuit 200 of the Related Art 2. As shown in FIG. 3, the PLL circuit 200 includes a phase comparator 211, a charge pump circuit 212, a loop filter 213, an adder 214, and a voltage-controlled oscillator 215.

The charge pump circuit 212 of the PLL circuit 200 includes two outputs. One of the outputs is controlled by a current source IPR, and the other output is controlled by a current source IPC. Then, a resistor R1 is connected between the one output and a ground voltage, and a capacitor C1 is connected between the other output and the ground voltage. The adder 214 adds a voltage across the resistor R1 of the loop filter 213 and a voltage at the capacitor C1. Then, the voltage-controlled oscillator 215 generates an output signal having a frequency corresponding to the voltage generated with the adder 214.

Assuming that almost no current flows into the capacitor C2, a voltage v(s) generated with the loop filter of the Related Art 1 is derived from Expression 1 based on R representing a resistance of the resistor R1, C representing a capacitance of the capacitor C1, a current i(s) flowing through the resistor R1 and a current i(s) flowing through the capacitor C1 in a Laplace area (the following expressions are all based on the Laplace area)

v(s)=R×i(s)+i(s)/sC (1)

With regard to a voltage generated with the loop filter 213 of the Related Art 2, a voltage expressed by the first term and a voltage expressed by the second term of Expression 1 are generated in a line connected with the resistor R1 and a line connected with the capacitor C1, respectively. In the Related Art 2, independently-generated voltages are added by the adder 214 to thereby generate a voltage equivalent to that of the Related Art 1. Further, the PLL circuit 200 adjusts current values of the current source IPR and the current source IPC to satisfy the relationship of Expression 1 even if a capacitance value of the capacitor C1 is small. As a result, the PLL circuit 200 can reduce a proportion of the capacitor C1 to the entire circuit area.

FIG. 4 is a block diagram of a PLL circuit 300 of the Related Art 3. As shown in FIG. 4, the PLL circuit 300 includes a first current generating circuit composed of a first charge pump circuit 312, a first loop filter 313, a first voltage-current converting circuit 314, and a first common-mode voltage control circuit 315, and a second current generating circuit composed of a second charge pump circuit 316, a second loop filter 317, a second voltage-current converting circuit 318, and a second common-mode voltage control circuit 319.

The PLL circuit 300 generates a current for controlling the current-controlled oscillator 320 in accordance with an integration value of a phase difference between the reference signal Fin and the output signal Fout. In addition, the second current generating circuit controls an offset of the phase difference between the reference signal Fin and the output signal Fout. Thus, the PLL circuit 300 can generate an output signal Fout with a small phase difference offset. Incidentally, the first charge pump circuit 312 and the second charge pump circuit 316 have the same circuit configuration.

FIG. 5 is a block diagram of a PLL circuit of the Related Art 4. Here, the block diagram of FIG. 5 shows the loop filter 114 of the PLL circuit 100 of the Related Art 1. The loop filter 400 of FIG. 5 includes a first filter unit 410, a current generating unit 411, a second filter unit 412, and an adding unit 413.

The first filter unit 410 generates a first voltage in accordance with a reference signal. Then, a first current corresponding to the first voltage is generated and output to the current generating unit. The current generating unit 411 generates a second current at a predetermined rate to the first current. The second current is converted into a second voltage by the second filter unit. Then, the adding unit 413 adds the first voltage and the second voltage to generate an output signal. As the first filter unit and the second filter unit, a capacitor having a large capacitance is generally used. However, the loop filter 400 can decrease the capacitance.

The PLL circuit 100 of the Related Art 1 requires the capacitor C1 having a large capacitance to remove noise generated in the charge pump circuit. In contrast, the circuit of the Related Art 2 can reduce a capacitance of the capacitor C1. However, the PLL circuit 200 of the Related Art 2 needs to add voltage values and thus has a problem that a circuit is upsized. In general, voltage values cannot be added only by connecting lines. An operational amplifier or the like as an adder is necessary for adding voltage values, for example. In addition, the loop filter 213 of the PLL circuit 200 of the Related Art 2 aims at removing only RF noise generated in the charge pump circuit and thus cannot remove ripple noise of a low frequency. This causes a problem that a phase of the output signal is unstabilized.

### SUMMARY

In one embodiment, there is provided a PLL circuit which includes: a first charge pump circuit to control an output current in accordance with an output signal of a phase comparator; an integrating filter to remove a predetermined frequency component from a voltage signal generated in accordance with an output current from the first charge pump circuit; a second charge pump circuit to output a larger current than the first charge pump circuit in accordance with the output signal from the phase comparator; a ripple filter to remove a ripple component from a voltage signal generated in accordance with an output current from the second charge pump circuit; a first voltage-current converting circuit to convert an output voltage from the integrating filter into a current; a second voltage-current converting circuit to convert an output voltage from the ripple filter into a current; and a current-controlled oscillator oscillating at an oscillation frequency based on sum total of the output current from the first voltage-current converting circuit and the output current from the second voltage-current converting circuit, the PLL circuit feeding an output signal of the current-controlled oscillator back to the phase comparator.

The PLL circuit according to the present invention can change an output current of the first charge pump circuit and a capacitance of the integrating filter to stabilize a transfer function determined by a ratio between an output current of the first charge pump circuit and a capacitance of the integrating filter. That is, the output current of the first charge pump circuit is decreased to reduce a capacitance of the integrating filter. Thus, the PLL circuit according to the present invention can reduce a capacitance of the integrating filter to save a circuit area of the PLL circuit.

The PLL circuit according to the present invention further includes a ripple filter. Thus, ripple noise generated in the second charge pump circuit can be reduced.

In addition, an output of the integrating filter and an output of the ripple filter are converted from a voltage to a current with the first and second voltage-current converting circuits, respectively. As a result, the PLL circuit according to the present invention can add output results of the integrating filter and the ripple filter only by connecting lines without adding voltages. Hence, a current including few noise components can be supplied to the current-controlled oscillator with a simple circuit configuration.

According to the PLL circuit of the present invention, it is possible to reduce a circuit area and generate an output signal of high phase stability.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a block diagram of a PLL circuit according to a first embodiment of the present invention;

FIG. 2 is a block diagram of a PLL circuit of the Related Art 1;

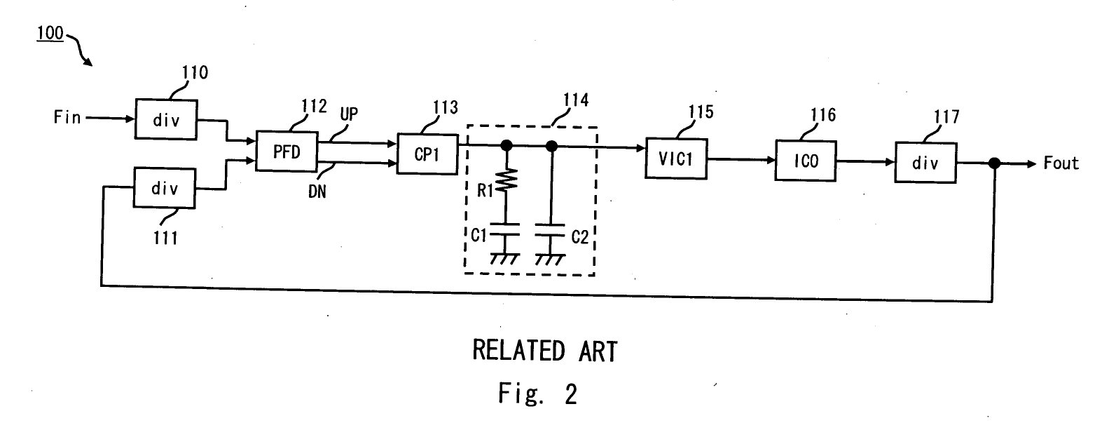

FIG. 3 is a block diagram of a PLL circuit of the Related Art 2;

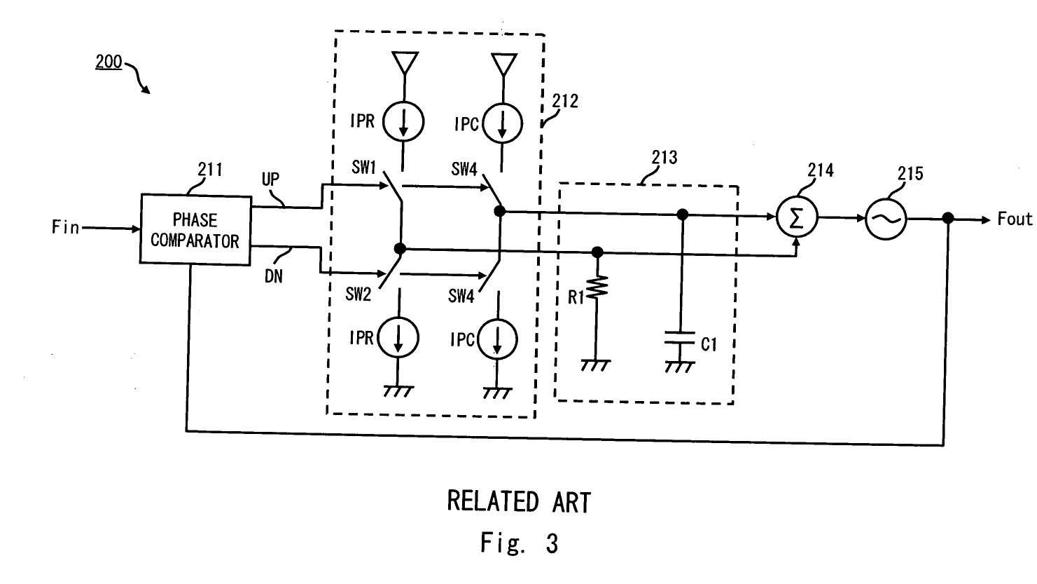

FIG. 4 is a block diagram of a PLL circuit of the Related Art 3; and

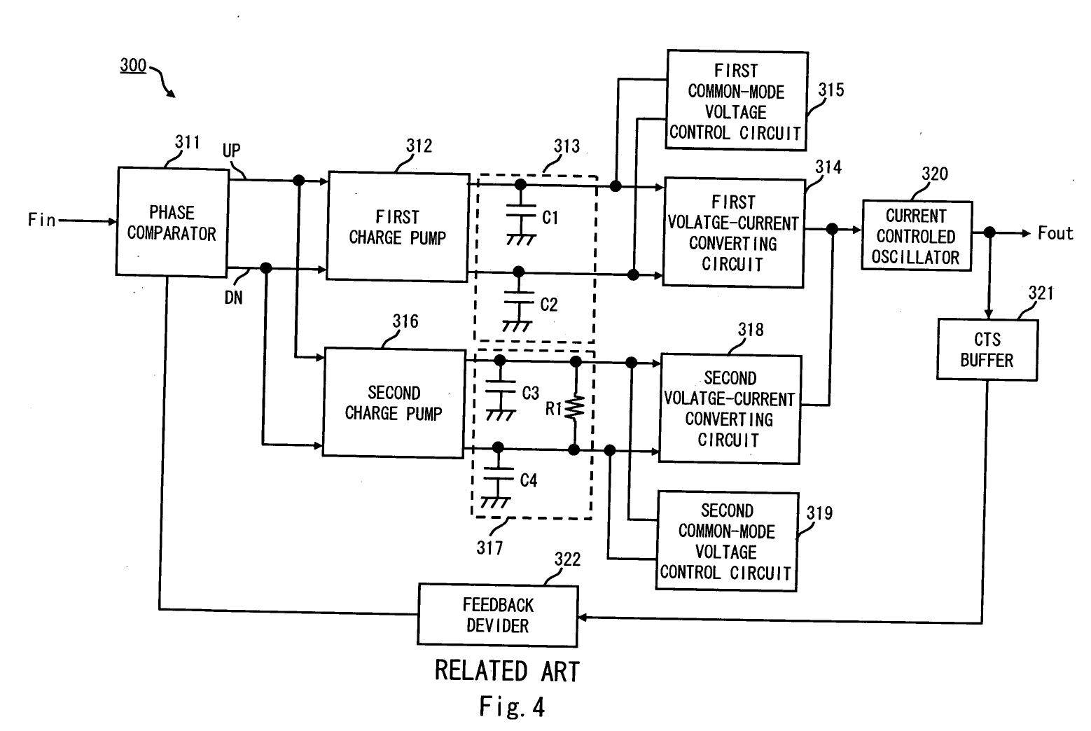

FIG. 5 is a block diagram of a PLL circuit of the Related Art 4.

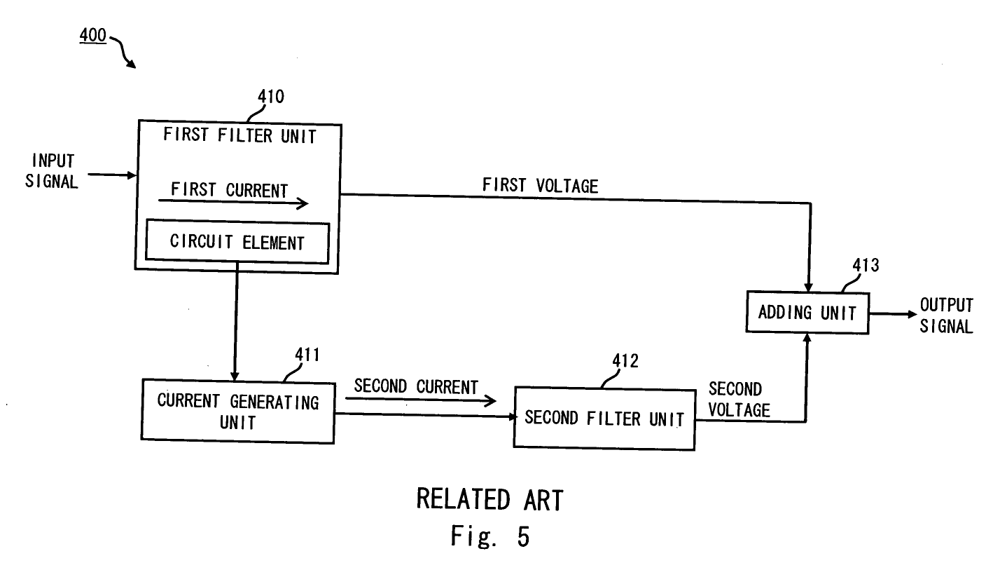

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Embodiment

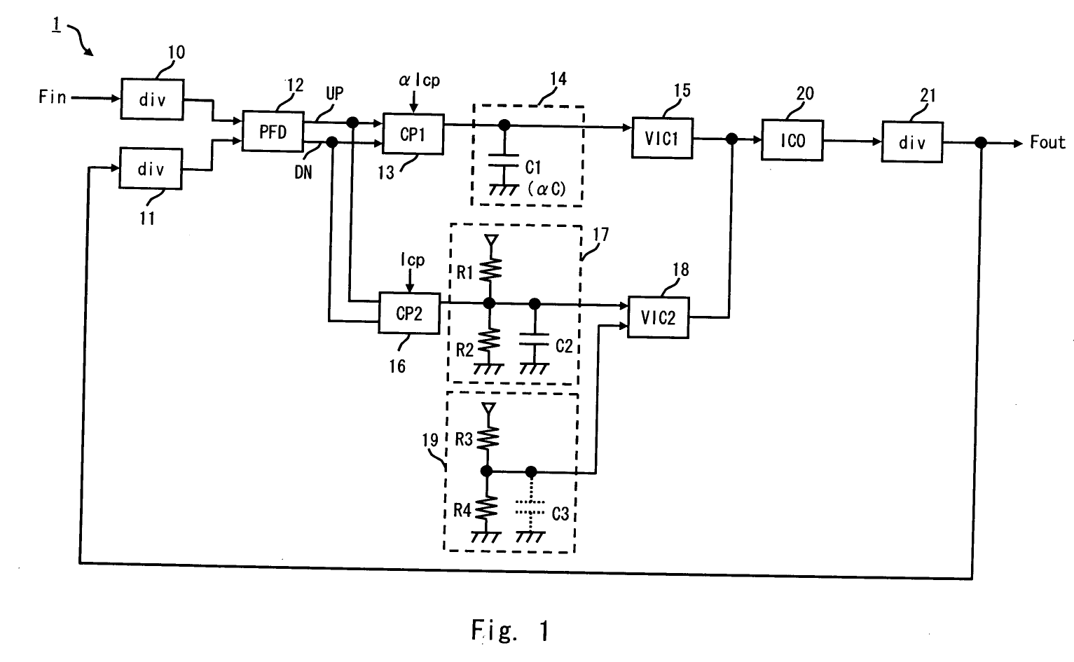

Hereinafter, an embodiment of the present invention will be described with reference to the accompanying drawings. FIG. 1 is a block diagram of a PLL circuit 1 according to a first embodiment of the present invention. As shown in FIG. 1, the PLL circuit 1 includes dividers 10, 11, 21, a phase comparator 12, a first charge pump circuit 13, an integrating filter 14, a first voltage-current converting circuit 15, a second charge pump circuit 16, a ripple filter 17, a second voltage-current converting circuit 18, a reference voltage generating circuit 19, and a current-controlled oscillator 20.

The divider 10 divides a frequency of a reference signal Fin and outputs the thus-divided signal. The divider 11 divides a frequency of an output signal Fout and outputs the thus-divided signal. The phase comparator 12 outputs a voltage-up signal UP and a voltage-down signal DN based on a phase difference between the output signal of the divider 10 and the output signal of the divider 11. The voltage-up signal UP and the voltage-down signal DN are, for example, pulse signals. If the output signal of the divider 11 has a phase delay relative to the output signal of the divider 10, a pulse width of the voltage-up signal UP is set longer than that of a voltage-down signal DN. On the other hand, if the output signal of the divider 10 has a phase delay relative to the output signal of the divider 11, a pulse width of the voltage-up signal UP is set shorter than a pulse width of the voltage-down signal DN. Further, if a phase of the output signal of the divider 10 matches with a phase of the output signal of the divider 11, a pulse width of the voltage-up signal UP is set equal to a pulse width of the voltage-down signal DN.

The first charge pump circuit 13 controls an output current based on the voltage-up signal UP and the voltage-down signal DN. For example, if a pulse width of the voltage-up signal UP is longer than a pulse width of the voltage-down signal DN, a current αIcp flows out during a period corresponding to a pulse width difference therebetween. On the other hand, if a pulse width of the voltage-up signal UP is shorter than a pulse width of the voltage-down signal DN, a current αIcp flows therein during a period during a period corresponding to a pulse width difference therebetween. Here, α represents a value of 0 to 1. Provided that α=1, an output current of the first charge pump circuit 13 is Icp, and an amount of the current is equal to that of a current Icp from the second charge pump circuit 16.

The integrating filter 14 filters out signals including predetermined frequency components generated in accordance with operations of the first charge pump circuit 13 (for example, RF noise). The integrating filter 14 includes a capacitor C1. The capacitor C1 is connected between an output of the first charge pump circuit 13 and a fourth power supply (for example, ground voltage). An output voltage of the first charge pump circuit 13 is determined based on the current αIcp from the first charge pump circuit 13 and a capacitance αC of the capacitor C1. The output voltage of the first charge pump circuit 13 is a transfer function of the integrating filter 14, which is expressed by the following expression. Provided that αi(s) represents the current αIcp from the first charge pump circuit 13, αC represents a capacitance of the capacitor C1, and v1(s) represents the output voltage of the first charge pump circuit 13, this transfer function is derived from Expression 2. Incidentally, a representing a capacitance of the capacitor C1 is the same as a of the first charge pump circuit 13.

v1(s)=αi(s)/sαC (2)

The first voltage-current converting circuit 15 outputs a current corresponding to an output voltage of the first charge pump circuit 13 through the integrating filter. That is, the current generated with the first voltage-current converting circuit 15 is a current generated on the basis of the voltage from which RF noise is removed by the integrating filter 14. Hence, the current generated with the first voltage-current converting circuit 15 includes fewer RF noise components.

The second charge pump circuit 16 controls an output current based on the voltage-up signal UP and the voltage-down signal DN. For example, if a pulse width of the voltage-up signal UP is longer than a pulse width of the voltage-down signal DN, the current Icp flows out during a period corresponding to a pulse width difference therebetween. On the other hand, if a pulse width of the voltage-up signal UP is shorter than a pulse width of the voltage-down signal DN, the current Icp flows therein during a period corresponding to a pulse width difference therebetween.

The ripple filter 17 filters out RF noise (for example, ripple noise), which is generated in accordance with operations of the second charge pump circuit 16. The ripple filter 17 includes a first resistor (for example, resistor R1), a second resistor (for example, resistor R2), and a capacitor C2. The resistor R1 is connected between a first power supply (for example, power supply voltage) and an output of the second charge pump circuit 16. The resistor R2 is connected between a second power supply (for example, ground voltage) and the output of the second charge pump circuit 16. The capacitor C2 is connected between the output of the second charge pump circuit 16 and a third power supply (for example, ground voltage). In the ripple filter 17, the capacitor C2 removes ripple noise out of noise generated at the output of the second charge pump circuit 16.

Here, if the resistors R1 and R2 have the same resistance value, 2R, an output voltage of the second charge pump circuit 16 is ½ of the power supply voltage in terms of DC voltage. On the other hand, considering an output voltage of the second charge pump circuit 16 in terms of AC voltage, the output voltage is given by the product of a resistance R and the output current Icp. That is, provided that the output voltage of the second charge pump circuit 16 is v2(s), and the output current Icp is i(s), the transfer function of the ripple filter is derived from Expression 3. Incidentally, in this example, almost no current flows in the capacitor C2.

v2(s)=R×i(s) (3)

The second voltage-current converting circuit 18 outputs a current corresponding to a differential voltage as a voltage difference between an output voltage of the second charge pump circuit 16 and a reference voltage generated with the reference voltage generating circuit 19 through the ripple filter 17. As described later, the reference voltage is a DC voltage that is equal to that of the ripple filter and is not influenced by ripple noise involved in operations of the second charge pump circuit 16. That is, a current generated with the second voltage-current converting circuit 18 is a current generated in accordance with a voltage from which RF noise is removed by the integrating filter 14. Hence, ripple noise components accompanying operations of the second charge pump circuit 16 are suppressed in a current generated with the second voltage-current converting circuit 18.

The reference voltage generating circuit 19 includes a third resistor (for example, resistor R3), and a fourth resistor (for example, resistor R4). The resistor R3 is connected between a fifth power supply (for example, power supply voltage) and an output line of the reference voltage generating circuit 19. The resistor R4 is connected between a sixth power supply (for example, ground voltage) and the output line of the reference voltage generating circuit 19. It is preferred that the resistors R3 and R4 have substantially the same resistance value as that of the resistors R1 and R2. Further, a capacitor C3 having the same capacitance as that of the capacitor C2 may be connected between the output line of the reference voltage generating circuit 19 and a ground voltage. As a result, an influence of noise in the power supply voltage generated in the ripple filter 17 corresponds to an influence of noise in the power supply voltage generated in the reference voltage generating circuit 19. The second voltage-current converting circuit 18 outputs a current corresponding to a differential voltage as a voltage difference between an output voltage of the second charge pump circuit 16 and the reference voltage. Therefore, if an influence of the noise of the power supply voltage generated in the ripple filter 17 and that in the reference voltage generating circuit 19 are balanced, the differential voltage due to the influence of noise of the power supply voltage is cancelled by the second voltage-current converting circuit 18. That is, an influence of noise of the power supply voltage on an output of the second voltage-current converting circuit 18 can be suppressed.

The current-controlled oscillator 20 changes an oscillation frequency of an output signal in accordance with an input current amount. An input current of this embodiment is the sum of an output current of the first voltage-current converting circuit 15 and an output current of the voltage-current converting circuit 18. The output signal of the current-controlled oscillator 20 is divided by the divider 21. Then, an output signal of the divider 21 is an output signal Fout of the PLL circuit 1. The output signal Fout is fed back to the divider 11.

Here, operations of the PLL circuit 1 are described. The PLL circuit 1 divides the reference signal Fin with the divider 10. Further, the output signal Fout is divided with the divider 11. Then, a phase of an output signal of the divider 10 is compared with that of the divider 11 by the phase comparator 12. Then, the phase comparator 12 generates the voltage-up signal UP and the voltage-down signal DN based on a phase difference therebetween. The first charge pump circuit 13 and the second charge pump circuit 16 output a current based on a difference between the pulse width of the voltage-up signal UP and the pulse width of the voltage-down signal DN. The output current flows out of the charge pump circuit if the pulse width of the voltage-up signal UP is longer than the pulse width of the voltage-down signal DN, for example. On the other hand, if the pulse width of the voltage-up signal UP is shorter than the pulse width of the voltage-down signal DN, the current flows in the charge pump circuit.

The output current of the first charge pump circuit 13 is converted into a voltage with the capacitor C1 of the integrating filter 14. At this time, the integrating filter 14 filters out RF noise generated in accordance with operations of the first charge pump circuit 13. Further, a voltage generated with the integrating filter 14 increases if an output current of the first charge pump circuit 13 flows out of the circuit. The voltage decreases if the output current flows in the circuit. Then, the first voltage-current converting circuit 15 outputs a current corresponding to the voltage converted by the integrating filter 14. Incidentally, an output current of the first charge pump circuit 13 is a times larger than that of the second charge pump circuit 16 (α is a value of 0 to 1).

On the other hand, an output current of the second charge pump circuit 16 is converted into a voltage through the ripple filter 17. In this embodiment, an output voltage of the ripple filter 17 is ½ of the power supply voltage in terms of DC voltage. Further, the output voltage varies in accordance with an output current of the second charge pump circuit 16 in terms of AC voltage. The variations of the AC voltage lead to ripple noise. The ripple filter 17 reduces the ripple noise. Then, a voltage with the reduced ripple noise is input to the second voltage-current converting circuit 18. The second voltage-current converting circuit 18 compares a reference voltage generated with the reference voltage generating circuit 19 with a voltage input through the ripple filter 17. Then, a current corresponding to the differential voltage is output. Voltage-current conversion characteristics in an applicable range of the second voltage-current converting circuit 18 are the same as those of the first voltage-current converting circuit 15.

An output of the first voltage-current converting circuit 15 and an output of the second voltage-current converting circuit 18 are connected together and then input to the current-controlled oscillator 20. That is, a current input to the current-controlled oscillator 20 is the sum of an output current of the first voltage-current converting circuit 15 and an output current of the second voltage-current converting circuit 18. Here, a voltage v(s) corresponding to a current input to the current-controlled oscillator 20 is the sum of voltages calculated by Expressions 2 and 3, and thus can be expressed by Expression 4. Here, the voltage is approximated on the assumption that almost no current flows through the capacitor C2.

$$\begin{matrix}v ( s ) = v 2 ( s ) + v 1 ( s ) \\ = R x i ( s ) + α i ( s ) / s α C \\ = R x i ( s ) + i ( s ) / s C\end{matrix} \qquad ( 4 )$$

As apparent from Expression 4, the transfer functions of the integrating filter 14 and the ripple filter 17 of this embodiment are the same as that of the loop filter of the PLL circuit of the related art. The current-controlled oscillator 20 controls an oscillation frequency of an output signal based on a current generated in accordance with such a voltage. Then, an output signal of the current-controlled oscillator 20 is divided by the divider 21 to thereby generate the output signal Fout. In addition, the output signal Fout is fed back and its phase is compared with a phase of the reference signal Fin. As a result, the phase of the output signal Fout is synchronous with the phase of the reference signal Fin.

As will be understood from the above, the PLL circuit 1 of this embodiment generates a voltage expressed by the first term of Expression 4 and a voltage expressed by the second term of Expression 4 with the ripple filter 17 and the integrating filter 14, respectively. Then, currents corresponding to the respective voltages are added to thereby generate a current corresponding to the voltage expressed by Expression 4 to control the current-controlled oscillator 20. That is, the ripple filter 17 and the integrating filter 14 can operate at different currents. This makes it possible to reduce an amount of current supplied to the integrating filter 14 as compared with a current supplied to the ripple filter 17. In addition, the capacitance of the capacitor C1 of the integrating filter 14 can be reduced based on a ratio α between the current supplied to the integrating filter 14 and the current supplied to the ripple filter 17.

At this time, the capacitance C of the capacitor is equal to the capacitance of the capacitor C1 of the loop filter 114 in the PLL circuit 100 of the Related Art 1. Then, the capacitance of the capacitor C1 of this embodiment is α times larger than the capacitance C, that is, αC. Thus, the capacitance αC is smaller than the capacitance C. Further, the current supplied to the integrating filter 14 is preferably a times larger than the current i(s) supplied to the ripple filter 17. This current value i(s) is equal to an output current value of the charge pump circuit 113 of the PLL circuit 100 of the Related Art 1. Thus, α of the current i(s) and α of the capacitance C of the capacitor in Expression 2 are cancelled, and the second term of Expression 4 can be approximated to that the PLL circuit of the related art.

That is, the PLL circuit 1 of this embodiment can reduce a capacitance of the capacitor C1. Further, as a result of reducing a capacitance of the capacitor C1, a circuit area can be reduced. The capacitor C1 occupies almost ½ of the circuit area of the PLL circuit 100 in the related art in some cases. The reduction in circuit area for the capacitor C1 greatly contributes to reduction of the entire circuit area.

Further, a resistance value of the resistors R1 to R4 is twice a resistance value R of the resistor R1 of the loop filter 114 in the PLL circuit 100 of the Related Art 1, that is, 2R. In addition, if a small amount of current flows through the capacitor C2 (capacitance C2), and its influence is not ignorable, the resistance value of the resistors R1 to R4 are set to 2R×C/(C+C2). Likewise, a current supplied to the ripple filter 17 is set to i(s)×C/(C+C2), and a current supplied to the integrating filter 14 is set to αi(s)×C/(C+C2). If the resistance value and the current value are thus corrected to thereby make the transfer function of the loop filter of this embodiment equal to the transfer function of the PLL circuit of the loop filter of the related art.

Further, the PLL circuit 1 of this embodiment generates a current in accordance with a voltage difference between a reference voltage generated with the reference voltage generating circuit 19 of the same configuration as that of the ripple filter 17 and a voltage generated with the ripple filter 17. As a result, noise superimposed to the power supply voltage is removed by the second voltage-current converting circuit 18. Therefore, the PLL circuit 1 of this embodiment can prevent an oscillation frequency from varying due to noise superimposed to the power supply voltage.

Further, the PLL circuit 1 of this embodiment converts a voltage generated through the integrating filter 14 and a voltage generated through the ripple filter 17 into a current with the voltage-current converting circuit. Then, the converted currents are added. The currents can be added only by connecting lines. That is, in the PLL circuit 1 of this embodiment, an adder using a operational amplifier circuit or the like is unnecessary to add voltages unlike the related art. Hence, the PLL circuit 1 of this embodiment can simplify the circuit configuration compared to the PLL circuits of the related art.

Incidentally, the present invention is not limited to the above embodiments but may be appropriately modified without departing from the scope of the invention. For example, in the above embodiments, a value of α of the current i(s) is equal to a value of α of the capacitance C of the capacitor, but the value of α of the current i(s) may be smaller than the value of α of the capacitance C of the capacitor. As a result, noise components in a current supplied to the current-controlled oscillator 20 can be further reduced. That is, according to the PLL circuit 1 of the present invention, the degree of freedom of a relationship between a circuit area and a level of noise components in a current for controlling an oscillation frequency can be improved.

It is apparent that the present invention is not limited to the above embodiment but may be modified and changed without departing from the scope and spirit of the invention.

What is claimed is:

1. A PLL circuit, comprising:
a first charge pump circuit to control an output current in accordance with an output signal of a phase comparator;
an integrating filter to remove a predetermined frequency component from a voltage signal generated in accordance with an output current from the first charge pump circuit;
a second charge pump circuit to output a larger current than the first charge pump circuit in accordance with the output signal from the phase comparator;
a ripple filter to remove a ripple component from a voltage signal generated in accordance with an output current from the second charge pump circuit;
a first voltage-current converting circuit to convert an output voltage from the integrating filter into a current;
a second voltage-current converting circuit to convert an output voltage from the ripple filter into a current; and
a current-controlled oscillator to control an frequency of an output signal based on sum total of the output current from the first voltage-current converting circuit and the output current from the second voltage-current converting circuit,
the PLL circuit feeding the output signal of the current-controlled oscillator back to the phase comparator.

2. The PLL circuit according to claim 1, wherein the ripple filter includes:
a first resistor connected between an output of the second charge pump circuit and a first power supply;
a second resistor connected between an output of the second charge pump circuit and a second power supply; and
a capacitor connected between an output of the second charge pump circuit and a third power supply.

3. The PLL circuit according to claim 2, wherein the integrating filter includes a capacitor connected between an output of the first charge pump circuit and a fourth power supply.

4. The PLL circuit according to claim 3, wherein the second to fourth power supplies have substantially the same potential.

5. The PLL circuit according to claim 1, wherein the integrating filter includes a capacitor connected between an output of the first charge pump circuit and a fourth power supply.

6. The PLL circuit according to claim 5, wherein an output current from the first charge pump circuit and an output current from the second charge pump circuit have a predetermined ratio, and a capacitance of the integrating filter is determined based on the predetermined ratio.

7. The PLL circuit according to claim 1, wherein the second voltage-current converting circuit is a voltage-current converting circuit to compare an output voltage of the ripple filter with a reference voltage to convert a differential voltage to a current.

8. The PLL circuit according to claim 2, wherein the second voltage-current converting circuit is a voltage-current converting circuit to compare an output voltage of the ripple filter with a reference voltage to convert a differential voltage to a current.

9. The PLL circuit according to claim 8, wherein the reference voltage is supplied to the second voltage-current converting circuit through a reference voltage line, and a value of the reference voltage is determined by a third resistor connected between the reference voltage line and the first power supply, and a fourth resistor connected between the reference voltage line and the second power supply.

10. The PLL circuit according to claim 9, wherein the first fourth resistors have substantially the same resistance value.
